(19) United States
(12) Patent Application Publication
(10) Pub. No.: US 2016/0170702 A1
(43) Pub. Date: Jun. 16, 2016

(54) DEVICES AND METHODS OF IMAGE-SPLITTING FOR DUAL-LAYER HIGH DYNAMIC RANGE DISPLAYS

(71) Applicant: Apple Inc., Cupertino, CA (US)

(72) Inventors: Jun Jiang, Campbell, CA (US); Cheng Chen, Cupertino, CA (US); Gabriel Marcu, San Jose, CA (US); Jiaying Wu, Santa Clara, CA (US)

(21) Appl. No.: 14/836,645

(22) Filed: Aug. 26, 2015

Related U.S. Application Data
(60) Provisional application No. 62/091,216, filed on Dec. 12, 2014.

(51) Int. Cl. G06F 3/14; H01L 27/12; G02F 1/1335; G02F 1/1368; G06T 5/00; G06T 1/20

(52) U.S. Cl. CPC G06F 3/1423; G06T 5/00; G06T 1/20; G02F 1/133528; G02F 1/1368; H01L 27/1259; H01L 27/124

(57) ABSTRACT

Systems and methods for reducing or eliminating image artifacts on a dual-layer liquid crystal display (LCD). By way of example, a system includes a first display panel and a second display panel. The system includes a processor coupled to the first display panel and the second display panel, and configured to generate a first image, and to generate a second image to be displayed on the first display panel based on the first image. The processor is configured to interpolate the second image. Interpolating the second image includes adjusting the second image according to a generated objective function bounded by a first constraint. The processor is configured to filter the second image, and to generate a third image to be displayed on the second display panel based on the first image and the second image. The third image is generated to prevent image artifacts on the second display panel.

### CROSS-REFERENCE TO RELATED APPLICATION

This application is a Non-Provisional patent application of U.S. Provisional Patent Application No. 62/091,216, entitled “Devices and Methods for Of Image-Splitting for Dual-Layer High Dynamic Range Displays,” filed Dec. 12, 2014, which is herein incorporated by reference in its entirety and for all purposes.

### BACKGROUND

The present disclosure relates generally to electronic displays and, more particularly, to dual-layer electronic displays.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Electronic displays commonly appear in electronic devices such as televisions, computers, and phones. One type of electronic display, known as a liquid crystal display (LCD), displays images by modulating the amount of light allowed to pass through a liquid crystal layer within pixels of the LCD. In general, LCDs modulate the light passing through each pixel by varying a voltage difference between a pixel electrode and a common electrode. This creates an electric field that causes the liquid crystal layer to change alignment. The change in alignment of the liquid crystal layer causes more or less light to pass through the pixel. By changing the voltage difference (often referred to as a data signal) supplied to each pixel, images are produced on the LCD.

In general, an LCD with a higher contrast ratio will produce clearer, lifelike images. Specifically, while the brightness of LCDs may typically be increased, the contrast ratio is usually not improved mainly due to light leakage. For example, the contrast ratio for typical LCDs is about 1000:1. To produce a display of better contrast ratio, some designs may stack two LCD panels (e.g., a front panel and a back panel) on top of each other. The resultant image may be optically combined by light transmitted through the front panel and back panel. However, because a relatively small distance may be present between the front panel and the back panel of the stacked LCD, images on the respective front panel and back panel may appear misaligned when viewed from certain viewing angles. This is known as parallax, or image artifacts that may cause images to appear as overlapping double images. Similarly, other image artifacts (e.g., halos) may become apparent due to certain image processing techniques.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Various embodiments of the present disclosure may reduce and/or substantially eliminate certain image artifacts (e.g., parallax artifacts, halo artifacts, clipping, and so forth) that may occur on dual-layer electronic displays. By way of example, a system may include an enclosure. The enclosure may include a first display panel and a second display panel. The second display panel may be coupled to the first display panel. The enclosure may also include one or more processors communicatively coupled to the first display panel and the second display panel. The one or more processors may be configured to generate a first image, generate a second image to be displayed on the first display panel based at least in part on the first image, and to interpolate the second image. Interpolating the second image may include adjusting the second image according to a generated objective function bounded by a first constraint. The one or more processors may also be configured to filter the second image, and to generate a third image to be displayed on the second display panel based at least in part on the first image and the interpolated and filtered second image. The third image may be generated to reduce or substantially prevent an occurrence of image artifacts on the second display panel.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Various aspects of this disclosure may be better understood upon reading the following detailed description and upon reference to the drawings in which:

FIG. 1 is a schematic block diagram of an electronic device including a dual-layer display, in accordance with an embodiment;

FIG. 2 is a perspective view of a notebook computer representing an embodiment of the electronic device of FIG. 1;

FIG. 3 is a front view of a hand-held device representing another embodiment of the electronic device of FIG. 1;

FIG. 4 is a front view of a desktop computer representing another embodiment of the electronic device of FIG. 1;

FIG. 5 is a front view of a media playing device representing another embodiment of the electronic device of FIG. 1;

FIG. 6 is a cross-sectional view of the dual-layer display included within the electronic device of FIG. 1, in accordance with an embodiment;

FIG. 7 is a cross-sectional view of the dual-layer display included FIG. 6 having certain layers removed, in accordance with an embodiment;

FIG. 8 is an equivalent circuit diagram illustrating a back panel and a front panel of the dual-layer display of FIG. 1, in accordance with an embodiment; and

FIG. 9 is a graphical flow diagram illustrating an embodiment of a process useful in reducing and/or substantially preventing occurrences of image artifacts on a dual-layer electronic display, in accordance with an embodiment.

### DETAILED DESCRIPTION

One or more specific embodiments of the present disclosure will be described below. These described embodiments are only examples of the presently disclosed techniques. Additionally, in an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

Embodiments of the present disclosure relate to systems, methods, and devices for reducing image artifacts on high dynamic range (HDR) dual-layer liquid crystal displays (LCDs). To produce a display of improved contrast ratio, it may be useful to stack two LCD panels (e.g., a front panel and a back panel) on top of each other. Specifically, if the dynamic range of a typical LCD is n, a dual-layer LCD may achieve a theoretical dynamic range of n². For example, the contrast ratio of the dual-layer display may be theoretically increased to 1,000,000 to 1 given that the contrast ratio of the front LCD panel and the back LCD panel is 1,000:1, respectively. This disclosure will describe systems and methods for achieving a high contrast ratio dual-layer display with reduced or no parallax or other image artifacts.

For the dual-layer display to properly display an image, an incoming image may be split into two images, or one respective image for each of the front LCD panel and the back LCD panel. The two images may be then combined optically and viewed from above the front LCD panel. However, because a relatively small distance may be present between the front panel and the back panel of the stacked LCD, images on the respective front panel and back panel may appear misaligned when viewed from certain viewing angles. Indeed, without the presently disclosed techniques, this may become apparent as visible artifacts known as parallax, or image artifacts that may cause images to appear as double images. Furthermore, the presently disclosed techniques may prevent other image artifacts (e.g., halos, clipping, etc) may otherwise occur on the dual-layer display.

Accordingly, in certain embodiments, to split the image while reducing parallax and/or other artifacts while achieving high contrast ratio and maintaining high dynamic range (HDR), it may be useful to provide an improved image-splitting process (e.g., image-splitting algorithm). In certain embodiments, the image-splitting process may include using upper constraints of an objective function as a starting point in the blurring and downsizing (e.g., downsampling) the image of the back LCD panel. Specifically, to prevent bright pixels of the incoming image from being overly dimmed during blurring or interpolation, the upper constraint may be used as starting point in the image-splitting. The image-splitting process may further include applying a guided filter may be on the blurred and downsized image of the back LCD panel to improve the uniformity of the image on the back LCD panel. This may specifically reduce the possibility of halo artifacts (e.g., image artifacts appearing near the edges of an image and/or near the edges of elements within the image) from becoming apparent in the images displayed on the front LCD panel and the back LCD panel. In other embodiments, the luminance of the dual-layer (e.g., two-panel) display may be increased by providing a higher aperture ratio, monochromatic, and lower resolution back LCD panel as compared to the front LCD panel. Moreover, to further reduce the possibility of parallax artifacts, the thickness of the dual-layer (e.g., two-panel) display may be reduced by removing one or more middle polarizer(s), an air gap, and a diffuser.

As used herein, “dual-layer” or “dual-cell” may refer to an electronic display including at least two display panels for displaying images, in which the two display panels may be constructed, for example, in a substantially stacked configuration. Additionally, “back panel” or “back LCD panel” may refer to one of two display panels of a dual-layer and/or dual-cell display that is positioned closest to, or faces the light source of the display. Similarly, “front panel” or “front LCD panel” may refer to one of two display panels of a dual-layer and/or dual-cell display that may be positioned foremost with respect to, or stacked atop the back panel or back LCD panel and may be the one of the two panels viewable to a user of the display.

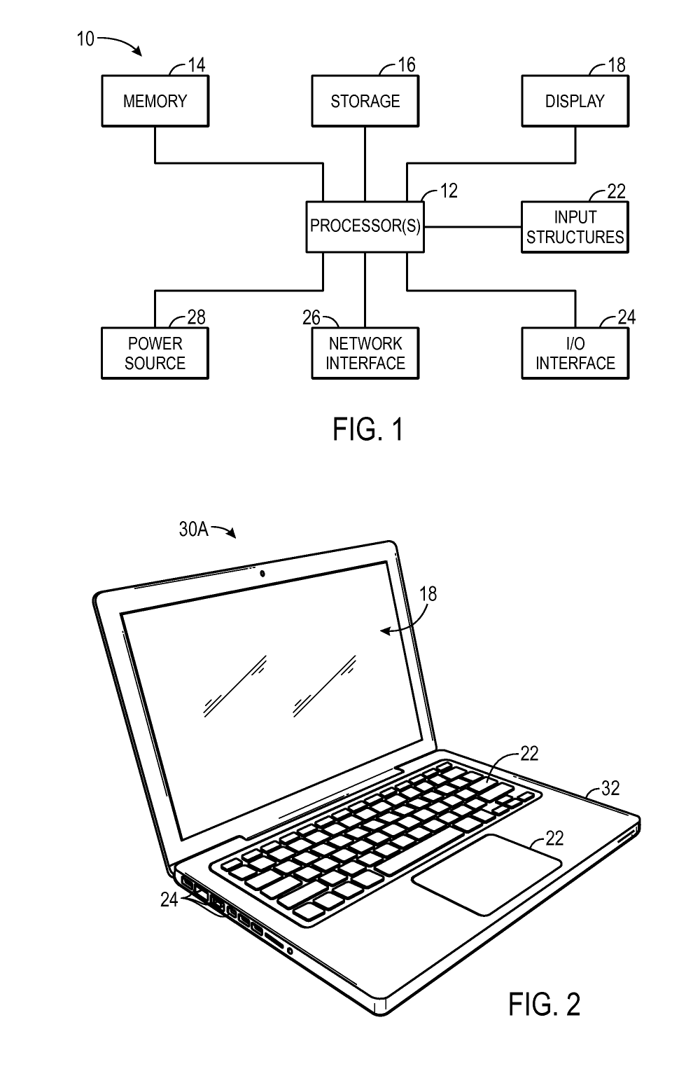

With the foregoing in mind, a general description of suitable electronic devices that may employ electronic touch screen displays having dual-layer (e.g., dual-cell) LCD panel components and are useful in reducing and/or substantially eliminating certain image artifacts (e.g., parallax artifacts, halo artifacts, clipping artifacts) that may become apparent on a dual-layer display will be provided below. Turning first to FIG. 1, an electronic device 10 according to an embodiment of the present disclosure may include, among other things, one or more processor(s) 12, memory 14, nonvolatile storage 16, a display 18 having dual-layer, input structures 22, an input/output (I/O) interface 24, network interfaces 26, and a power source 28. The various functional blocks shown in FIG. 1 may include hardware elements (including circuitry), software elements (including computer code stored on a computer-readable medium) or a combination of both hardware and software elements. It should be noted that FIG. 1 is merely one example of a particular implementation and is intended to illustrate the types of components that may be present in electronic device 10.

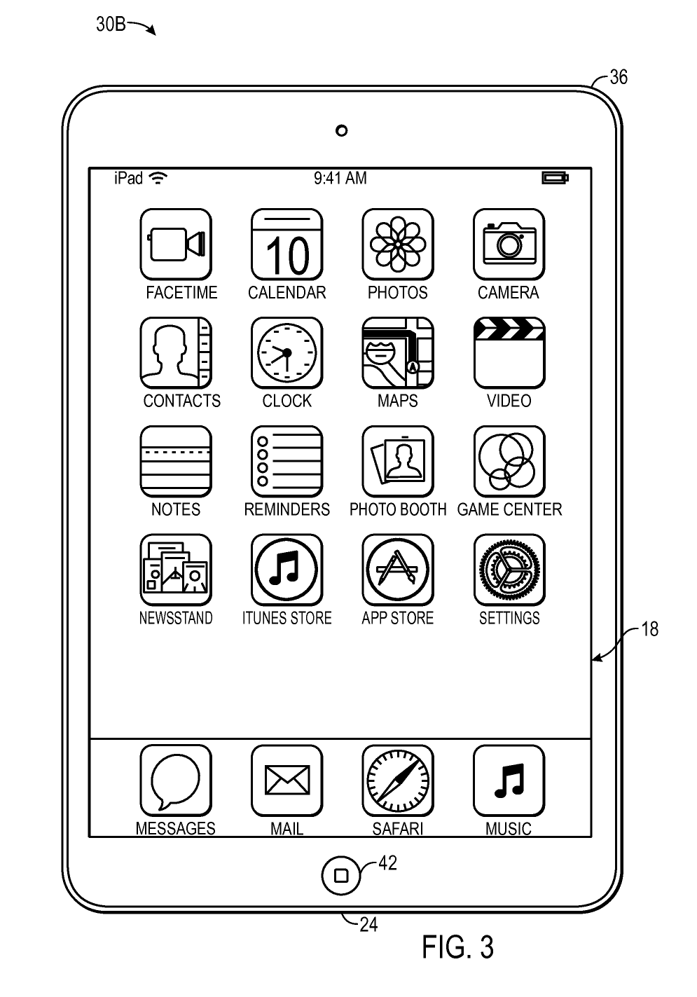

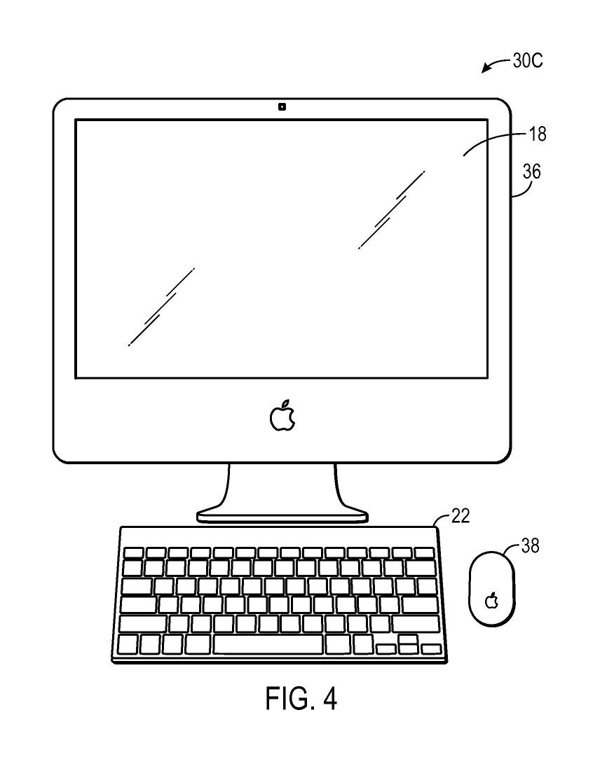

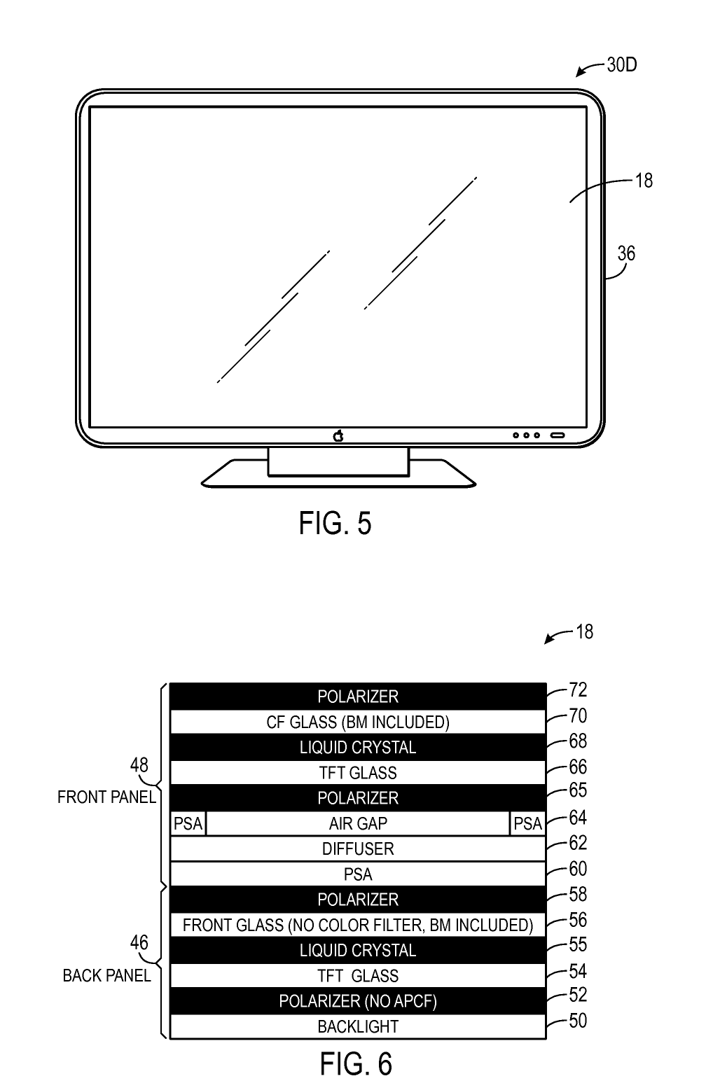

By way of example, the electronic device 10 may represent a block diagram of the notebook computer depicted in FIG. 2, the handheld device depicted in FIG. 3, the desktop computer depicted in FIG. 4, the television depicted in FIG. 5, or similar devices. It should be noted that the processor(s) 12 and/or other data processing circuitry may be generally referred to herein as “data processing circuitry.” Such data processing circuitry may be embodied wholly or in part as software, firmware, hardware, or any combination thereof. Furthermore, the data processing circuitry may be a single contained processing module or may be incorporated wholly or partially within any of the other elements within the electronic device 10.

In the electronic device 10 of FIG. 1, the processor(s) 12 and/or other data processing circuitry may be operably coupled with the memory 14 and the nonvolatile memory 16 to perform various algorithms for displaying high contrast ratio and high dynamic range (HDR) on the display 18. Such programs or instructions executed by the processor(s) 12 may be stored in any suitable article of manufacture that includes one or more tangible, computer-readable media at least collectively storing the instructions or routines, such as the memory 14 and the nonvolatile storage 16. The memory 14 and the nonvolatile storage 16 may include any suitable articles of manufacture for storing data and executable instructions, such as random-access memory, read-only memory, rewritable flash memory, hard drives, and optical discs. Also, programs (e.g., an operating system) encoded on such a computer program product may also include instructions that may be executed by the processor(s) 12 to enable the electronic device 10 to provide various functionalities.

In certain embodiments, the display 18 may be a dual-layer liquid crystal display (LCD) (e.g., including a back panel and a front panel), which may allow users to view images generated on the electronic device 10 with a higher contrast ratio and higher dynamic range (HDR). Specifically, as will be further appreciated, the display 18 may include two or more LCD panels (e.g., back panel and front panel) in a stacked configuration, such that the backlight of the dual-layer LCD may be modulated at least twice as the light passes through the dual LCD panels. In some embodiments, the display 18 may include a touch screen, which may allow users to interact with a user interface of the electronic device 10. Furthermore, it should be appreciated that, in some embodiments, the dual-layer display 18 may include one or more organic light emitting diode (OLED) displays, or some combination of LCD panels and OLED panels.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interfaces 26. The network interfaces 26 may include, for example, interfaces for a personal area network (PAN), such as a Bluetooth network, for a local area network (LAN), such as an 802.11x Wi-Fi network, and/or for a wide area network (WAN), such as a 3G or 4G cellular network. The power source 28 of the electronic device 10 may be any suitable source of power, such as a rechargeable lithium polymer (Li-poly) battery and/or an alternating current (AC) power converter.

The electronic device 10 may take the form of a computer, a television, or other type of electronic device. Such computers may include computers that are generally portable (such as laptop, notebook, and tablet computers) as well as computers that are generally used in one place (such as conventional desktop computers, workstations and/or servers). In certain embodiments, the electronic device 10 in the form of a computer may be a model of a MacBook®, MacBook® Pro, MacBook Air®, iMac®, Mac® mini, or Mac Pro® available from Apple Inc. By way of example, the electronic device 10, taking the form of a notebook computer 30A, is illustrated in FIG. 2 in accordance with one embodiment of the present disclosure. The depicted computer 30A may include a housing or enclosure 32, a display 18, input structures 22, and ports of an I/O interface 24. In one embodiment, the input structures 22 (such as a keyboard and/or touchpad) may be used to interact with the computer 30A, such as to start, control, or operate a GUI or applications running on computer 30A. For example, a keyboard and/or touchpad may allow a user to navigate a user interface or application interface displayed on display 18.

FIG. 3 depicts a front view of a handheld device 30B, which represents one embodiment of the electronic device 10. The handheld device 30B may represent, for example, a portable phone, a media player, a personal data organizer, a handheld game platform, or any combination of such devices. By way of example, the handheld device 30B may be a tablet-sized embodiment of the electronic device 10, which may be, for example, a model of an iPad® available from Apple Inc of Cupertino, Calif.

The handheld device 30B may include an enclosure 36 to protect interior components from physical damage and to shield them from electromagnetic interference. The enclosure 36 may surround the display 18, which may display indicator icons 38. The indicator icons 38 may indicate, among other things, a cellular signal strength, Bluetooth connection, and/or battery life. The I/O interfaces 24 may open through the enclosure 36 and may include, for example, a proprietary I/O port from Apple Inc. to connect to external devices.

User input structures 40, 42, 44, and 46, in combination with the display 18, may allow a user to control the handheld device 30B. For example, the input structure 40 may activate or deactivate the handheld device 30B, the input structure 42 may navigate user interface to a home screen, a user-configurable application screen, and/or activate a voice-recognition feature of the handheld device 30B, the input structures 44 may provide volume control, and the input structure 46 may toggle between vibrate and ring modes. A microphone 48 may obtain a user's voice for various voice-related features, and a speaker 50 may enable audio playback and/or certain phone capabilities. A headphone input 52 may provide a connection to external speakers and/or headphones.

Turning to FIG. 4, a computer 30C may represent another embodiment of the electronic device 10 of FIG. 1. The computer 30C may be any computer, such as a desktop computer, a server, or a notebook computer, but may also be a standalone media player or video gaming machine. By way of example, the computer 30C may be an iMac®, a MacBook®, or other similar device by Apple Inc. It should be noted that the computer 30C may also represent a personal computer (PC) by another manufacturer. A similar enclosure 36 may be provided to protect and enclose internal components of the computer 30C such as the dual-layer display 18. In certain embodiments, a user of the computer 30C may interact with the computer 30C using various peripheral input devices, such as the keyboard 22 or mouse 38, which may connect to the computer 30C via a wired and/or wireless I/O interface 24.

Similarly, FIG. 5 depicts a standalone media player 30D representing another embodiment of the electronic device 10 of FIG. 1 that may be configured to operate using the techniques described herein. By way of example, the standalone media player 30D may be an AppleTV® device by Apple, Inc. However, the standalone media player 30D may also represent a media player or video game console monitor, or other device by another manufacturer.

In certain embodiments, as previously noted above, each embodiment (e.g., notebook computer 30A, handheld device 30B, computer 30C, media player 30D) of the electronic device 10 may include a dual-layer display 18, which may include two or more LCD panels (e.g., back panel and front panel) constructed in a stacked configuration (e.g., a front display panel stacked atop a back display panel or a front display panel positioned foremost with respect to a back display panel). Specifically, as will be further appreciated, a light source (e.g., backlight) of the dual-layer LCD may be modulated twice as the light passes through the back panel and the front panel, and, thus, the total contrast ratio of the display 18 may be theoretically equal to, for example, the product of the contrast ratio (e.g., 1,000:1) of the back panel and the contrast ratio (e.g., 1,000:1) of the front panel. Thus, as the resultant image to be displayed on the display 18 may be optically combined by the light transmitted through the back panel and the front panel, the total contrast ratio of the display 18 may be increased to, for example, 1,000,000:1 by providing the dual-layer configuration of the display 18.

With the foregoing in mind, FIG. 6 depicts a cross-sectional view showing the various device layers that may be included as part of the dual-layer display 18. As illustrated, and as previously discussed, the dual-layer display 18 may include at least a back LCD panel 46 and a front LCD panel 48. As depicted, the back LCD panel 46 may include a top polarizing layer 58 and a corresponding bottom polarizing layer 52 each configured to polarize light emitted by a light source 50 (e.g., backlight). The light source 50 may, in some embodiments, include a backlight assembly unit or a light-reflective surface. For example, the light source 50 may include any type of suitable lighting device, such as cold cathode fluorescent lamps (CCFLs), hot cathode fluorescent lamps (HCFLs), and/or light emitting diodes (LEDs), or other light source that may be utilize to provide highly bright lighting.

As further depicted, the back LCD panel 46 may also include a thin film transistor (TFT) layer 54 illustrated as being disposed above the bottom polarizing layer 52. For simplicity of illustration, the TFT layer 54 is depicted as a generalized structure in FIG. 6. However, it should be appreciated that the TFT layer 54 may itself include various conductive, non-conductive, and semiconductive layers and structures, which may generally form the electrical devices and pathways which drive the operation of pixels of the display 18. For example, as will be further appreciated, the TFT layer 54 may include the respective data lines (also referred to as “source lines”), scanning lines (also referred to as “gate lines”), pixel electrodes, and common electrodes (as well as other conductive traces and structures).

As further depicted, a liquid crystal (LC) layer 55 may be disposed over the TFT layer 54. The LC layer 55 may include liquid crystal molecules suspended in a fluid or embedded in polymer networks that may be oriented or aligned with respect to an electrical field generated by the TFT layer 54. Thus, the orientation of the liquid crystal molecules in the LC layer 55 may determine the amount of light (e.g., provided by the light source 50) that is transmitted through pixels of the back LCD panel 46. For example, applying a voltage to the TFT layer 54 of the pixel may generate an electric field in the LC layer 55, such that the liquid crystal molecules in the LC layer 55 may be aligned to affect the polarization of light propagating through the LC layer 55. Based on the polarization of the light passing out from the liquid crystal layer 56, the light may be absorbed by the top polarizer 58 or transmitted through the top polarizer 58.

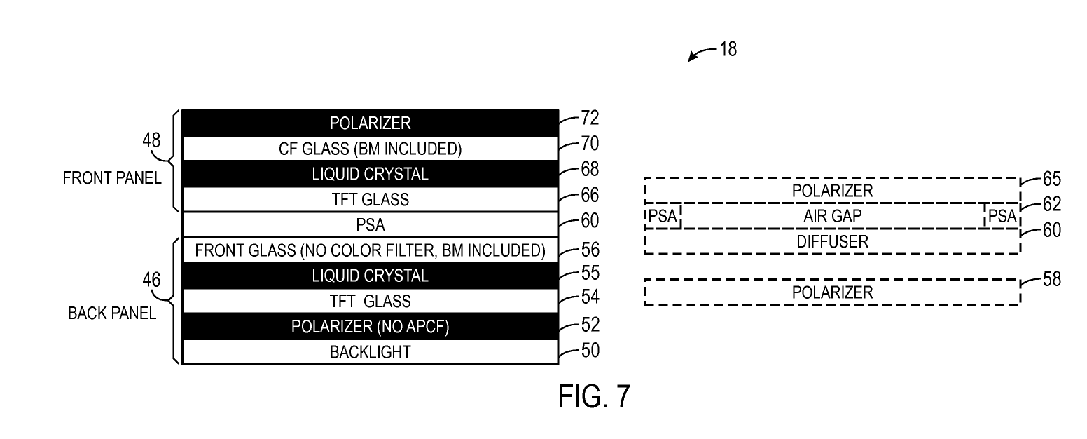

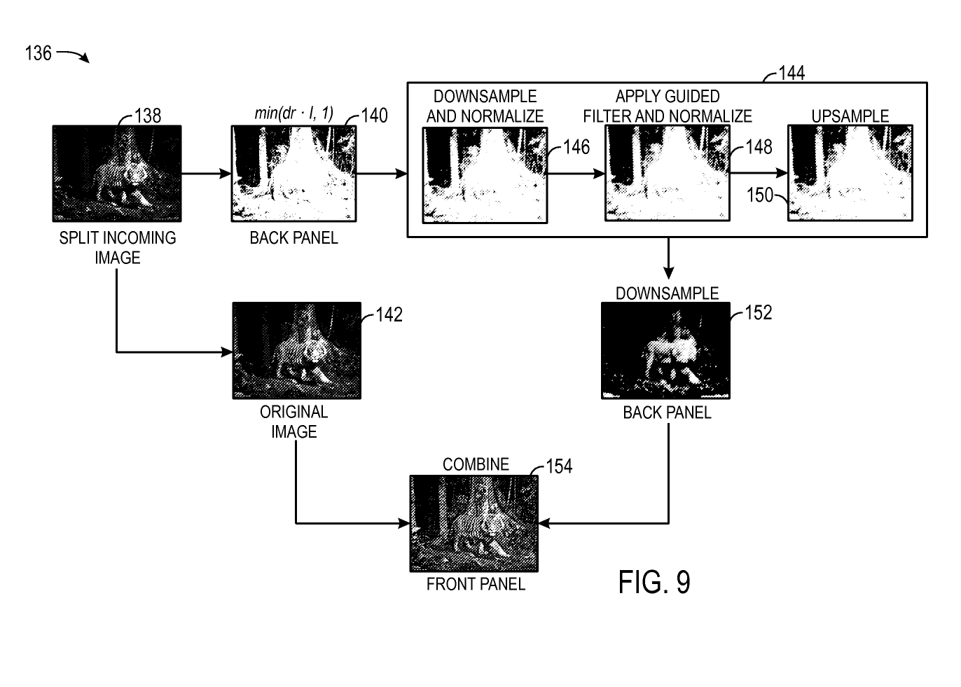

Disposed between the LC layer 55 and the top polarizing layer 58 may be a front glass 56 of the back LCD panel 46. The front glass 56 may include a transparent conductive material such as, for example, indium tin oxide (ITO) or indium zinc oxide (IZO). As will be further discussed with respect to FIGS. 7 and 9, the back LCD panel 46 may not include a color filter layer. Specifically, as will be discussed, the back LCD panel 46 may include an all grayscale display panel, as an additional color filter layer in the back LCD panel 46 may further attenuate the transmittance of the light transmitted from the light source 50 (e.g., backlight).

In certain embodiments, as further illustrated by FIG. 6, the front LCD panel 48 may be stacked atop (e.g., directly atop), and may be electrically coupled to the back LCD panel 46. Specifically, the front LCD panel 48 may include pressure sensitive adhesive (PSA) layer 60 that may be used, for example, to bond the back LCD panel 46 to the front LCD panel 48. Disposed above the PSA layer 60 may be a diffuser layer 62, which may be provided to diffuse and/or reflect light of multiple wavelengths and/or polarizations in a plane of incidence. As further depicted, an air gap 64 may be provided to separate the diffuser layer 62 and a bottom polarizing layer 65 of the front LCD panel 48. Specifically, similar to the back LCD panel 46, the front LCD panel 48 may also include a bottom polarizing layer 65 and a corresponding top polarizing layer 72 each configured to polarize light emitted by the light source 50 (e.g., backlight).

In certain embodiments, as also similar to the back LCD panel 46, the front LCD panel 48 may also include a separate TFT layer 66 and a separate LC layer 68. The TFT layer 66 and the LC layer 68 may include a similar construction and may operate similarly to the TFT layer 54 and the LC layer 55 of the back LCD panel 46. However, different from the back LCD panel 46, the front LCD panel 48 may include a color filer layer 70 disposed between the TFT layer 54 and the top polarizer layer 72. The color filter layer 70 may include, for example, a red, green, or blue filter, such that each unit pixel of the display 18 may correspond to a primary color when light is transmitted from the light source 50 (e.g., backlight) through the back LCD panel 46 and the front LCD panel 48.

As previously noted, providing the dual-layer display 18 (e.g., dual-cell display) with two or more LCD panels (e.g., back LCD panel 46 and the front LCD panel 48) in a stacked configuration as illustrated in FIG. 6 may markedly increase the total contrast ratio, as well as the dynamic range and bit depth of the display 18. However, in certain embodiments, in order for the dual-layer display 18 to properly display images on the dual-layer display 18, two respective images may be required to be generated for the back LCD panel 46 and the front LCD panel 48 based on an incoming original image signal. The respective images may be then optically combined and viewed from above the front LCD panel 48 of the dual-layer display 18. However, certain image-splitting techniques based on the ideal case of having perfect or near perfect alignment between the back LCD panel 46 and front LCD panel 48 may lead to image artifacts (e.g., parallax errors or halos) becoming apparent on the dual-layer display 18. Specifically, the two images may appear markedly misaligned (e.g., appearing as an overlapping double image) to a user when viewed from certain viewing angles.

Indeed, in some embodiments, at least some distance and/or misalignment may exist between pixels of the back LCD panel 46 and pixels of the front LCD panel 48 due to, for example, the number of polarizing layers (e.g., polarizing layers 52, 58, 65, and 72) and other components between the LC layers 55 and 68 of the back LCD panel 46 and the front LCD panel 48. Other image errors such as, for example, clipping errors or moiré errors may also become apparent on the display 18 when the image computed for the back LCD panel 46 is improperly blurred or overly constrained. For example, the incoming original image (e.g., pre image-splitting) may include pixel values that are brighter (e.g., whiter) than the highest grayscale voltage level of the front LCD panel 48 or darker (e.g., blacker) than the lowest grayscale voltage level of the front LCD panel 48. These pixel values may be “clipped” (e.g., recalculated as a default value), and may thus appear as an image artifact when the display 18 attempts to reconstruct the original image on the front LCD panel 48 of the dual-layer display 18. Accordingly, as will be further appreciated with respect to FIGS. 7-13, to reduce possible image errors (e.g., parallax, halos, clipping artifacts, and so forth) while providing a high contrast ratio, high dynamic range (HDR), and high bit depth electronic display, it may be useful to reduce the number of device layers of the dual-layer display 18, as well as to provide an improved image-splitting process (e.g., image-splitting algorithm).

For example, in certain embodiments, as illustrated in FIG. 7, it may be useful to reduce the distance (e.g., thickness) between the LC layers 55 and 68 of the back LCD panel 46 and the front LCD panel 48 by removing, for example, one or more device layers of the back LCD panel 46 and/or the front LCD panel 48. For example, as depicted in FIG. 7, the polarizing layers 58 and 65, the diffuser 60, and the air gap 62 may be removed to reduce the distance (e.g., thickness) between the LC layers 55 and 68 of the back LCD panel 46 and the front LCD panel 48. Thus, the back LCD panel 46 may include only the polarizing layer 52 (e.g., having the polarizing layer 58 removed), which may serve as the bottom polarizing layer for the complete dual-layer display 18. Similarly, the front LCD panel 48 may include only the polarizing layer 72 (e.g., having the polarizing layer 65 removed), which may serve as the top polarizing layer for the complete dual-layer display 18. In this way, by providing the dual-layer display 18 with a reduced thickness, or reduced distance between the LC layers 55 and 68 of the back LCD panel 46 and the front LCD panel 48, possible occurrences of parallax becoming apparent on the display 18 may be reduced because the light transmittance of the light from the light source 50 may experience considerably less attenuation.

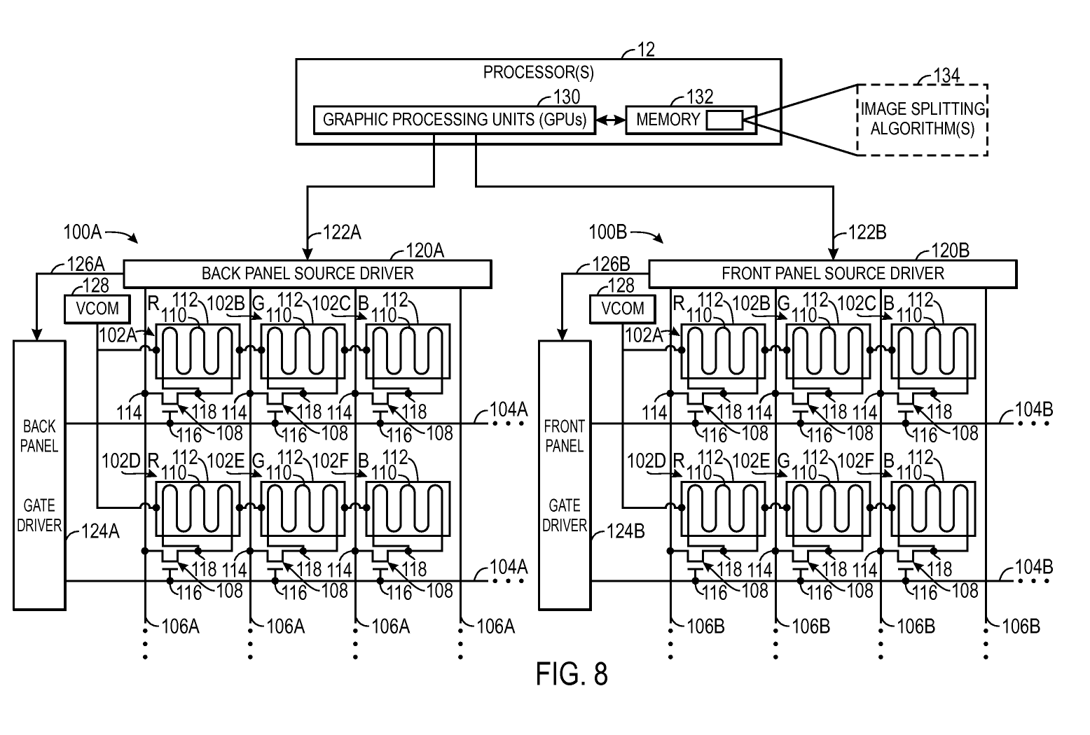

Turning now to FIG. 8, which generally represents an equivalent circuit diagram of, for example, the respective TFT layers 54 and 66 of the dual-layer display 18 in accordance with some embodiments. In particular, the dual-layer display 18 may include respective pixel arrays 100A and 100B. As illustrated, the respective pixel arrays 100A and 100B may include a number of unit pixels 102 disposed in respective pixel arrays or matrices. In these arrays, each unit pixel 102 may be defined by the intersection of rows and columns, represented by gate lines 104A and 104B (also referred to as scanning lines), and data lines 106A and 106B (also referred to as data lines), respectively. Although only 6 unit pixels 102, referred to individually by the reference numbers 102a-102f, respectively, are shown for purposes of simplicity, it should be understood that in an actual implementation, each of the data lines 106A and 106B and the gate lines 104A and 104B may include hundreds or thousands of such unit pixels 102. Each of the unit pixels 102 may represent one of three subpixels that respectively filters only one color (e.g., red, blue, or green) of light through, for example, a color filter. For purposes of the present disclosure, the terms “pixel,” “subpixel,” and “unit pixel” may be used largely interchangeably.

In the presently illustrated embodiment, each unit pixel 102 may include a thin film transistor (TFT) 108 for switching a data signal stored on a respective pixel electrode 110. The potential stored on the pixel electrode 110 relative to a potential of a common electrode 112 (e.g., creating a liquid crystal capacitance C_{LC}), which may be shared by other pixels 102, may generate an electrical field sufficient to alter the arrangement of liquid crystal molecules (not illustrated in FIG. 8). In the depicted embodiment of FIG. 8, a source 114 of each TFT 108 may be electrically connected to a data line 106A and 106B and a gate 116 of each TFT 108 may be electrically connected to a gate line 104A and 104B. A drain 118 of each TFT 108 may be electrically connected to a respective pixel electrode 110. Each TFT 108 may serve as a switching element that may be activated and deactivated (e.g., turned “ON” and turned “OFF”) for a predetermined period of time based on the respective presence or absence of a scanning signal on the gate lines 104A and 104B that are applied to the gates 116 of the TFTs 108.

When activated, a TFT 108 may store the image signals received via the respective data lines 106A and 106B as a charge upon its corresponding pixel electrode 110. As noted above, the image signals stored by the pixel electrode 110 may be used to generate an electrical field between the respective pixel electrode 110 and a common electrode 112. This electrical field may align the liquid crystal molecules to modulate light transmission through the pixel 102. Furthermore, although not illustrated, it should be appreciated that each unit pixel 102 may also include a storage capacitor C_{ST} that may used to sustain the pixel electrode voltage (e.g., Vₚᵢₓₑₗ) during the time in which the TFTs 108 may be switch to the “OFF” state.

The dual-layer display 18 may also include respective source driver integrated circuits (IC) 120A and 120B corresponding to the back LCD panel 46 and the front LCD panel 48. The respective source driver ICs 120A and 120B may include a chip, such as a processor or application specific integrated circuit (ASIC) that controls the respective display pixel arrays 100A and 100B by receiving image data 122A and 122B (e.g., split images) from the processor(s) 12, and sending the corresponding split image signals to the unit pixels 102 of the respective pixel arrays 100A and 100B. The respective source drivers 120A and 120B may also provide respective timing signals 126A and 126B to, for example, respective gate drivers 124A and 124B to facilitate the activation/deactivation of individual rows of pixels 102. In other embodiments, timing information may be provided to the gate driver 124 in some other manner. The display 18 may or may not include a common voltage (VCOM) source 128 to provide a common voltage (VCOM) voltage to the common electrodes 112. In certain embodiments, the VCOM source 128 may supply a different VCOM to different common electrodes 112 at different times. In other embodiments, the common electrodes 112 all may be maintained at the same potential or similar potential.

In certain embodiments, as further illustrated in FIG. 8, the processor(s) 12 may include one or more graphics processing units (GPUs) 130 that may be used to generate and render split images to each of the back LCD panel 46 and the front LCD panel 48. In one embodiment, the one or more GPUs 130 may be communicatively coupled to an internal memory 132. In certain embodiments, the internal memory 132 may store one or more image splitting processes 134 for providing the image data 122A to the pixel array 100A of the back LCD panel 46 and providing the image data 122B to the pixel array 100B of the front LCD panel 48. The image-splitting process 134 (e.g., image-splitting algorithm(s) 134) may include any code or instructions that, when executed by the GPUs 130 and/or the processor(s) 12 at large, may be useful in calculating, splitting, and processing image data to be displayed on the dual-layer display 18. It should be appreciated that while the image-splitting process 134 may be illustrated as being executed by the GPUs 130, in other embodiments, the image-splitting process 134 (e.g., image-splitting algorithm(s) 134) may be executed by the respective source drivers 120A and 120B, or by other data processing circuitry that may be included as part of the processor(s) 12.

Turning now to FIG. 9, a graphical flow diagram is presented, illustrating an embodiment of a process 136 (e.g., corresponding to the image-splitting process 134) useful in reducing and/or substantially image artifacts (e.g., parallax, halos, clipping artifacts, and so forth) on a HDR dual-layer electronic display while providing high contrast ratio images by using, for example, the one or more processor(s) 12 included within the system 10 depicted in FIG. 1. The process 136, which may be illustrative of the image-splitting process 134 as discussed above with respect to FIG. 8, may include code or instructions stored in a non-transitory machine-readable medium (e.g., the memory 14 or the internal memory 132) and executed, for example, by the one or more processor(s) 12, the GPUs 130, and/or the source drivers 120A and 120B included within the system 10 and illustrated in FIG. 8.

The process 136 may begin with the GPUs 130 generating one or more images (e.g., still images and/or video images) to be displayed on the dual-layer display 18. As illustrated, the process 136 may then continue with the GPUs 130 splitting (process step and image 138) the one or more images into at least two individual images. Specifically, in certain embodiments, for the dual-layer display 18 system to properly display an image (e.g., still images and/or video images), the incoming image may be divided into two images to respectively drive the back LCD panel 46 (e.g., as illustrated by process step and image 140) and the front LCD panel 48 (e.g., as illustrated by process step and image 142) of the dual-layer display 18.

However, to reduce parallax caused by the distance between the back LCD panel 46 and front LCD panel 48, the process 136 may continue with the GPUs 130 blurring (process step and image 140) the split image provided to the back LCD panel 46. For example, in certain embodiments, the GPUs 130 may blur the image of the back LCD panel 46 (e.g., as illustrated by process step and image 140) by utilizing one or more constrained optimization techniques (e.g., mathematical approximation and computation models) to ensure that the blurring of the image of the back LCD panel 46 may be controlled not only to prevent parallax, but also to prevent halos clipping artifacts that may become apparent when brighter image objects surrounded by a darker background are displayed on the dual-layer display 18.

By way of example, in certain embodiments, the GPUs 130 may define one or more objective functions (e.g., scalar objective functions, linear or nonlinear least squares objective functions, multivariable equation solving objective functions, multi-objective objective functions, linear or quadratic programming objective functions, and so forth) that may be useful in computing an output of the function and searching for one or more solutions that drives the objective function to a maximum or minimum value. However, because it may be desirable to blur the image of the back LCD panel 46 insofar as to prevent parallax, but not to the extent that the image of the front LCD panel 48 may be susceptible to clipping artifacts, the GPUs 130 may apply certain optimized constraints to the defined objective function when blurring the image (e.g., image 140) of the back LCD panel 46. For example, in one embodiment, the GPUs 130 may define an objective function including upper constraints and lower constraints that may be expressed as:

$$max ( \frac{1}{dr} , {I}_{i , j} ) \leq {BP}_{i , j} \leq min ( dr \times {I}_{i , j} , 1 ) . \qquad equation ( 1 )$$

In the above equation (1), BP_{i,j} may represent the pixel value at (i,j) on the back LCD panel 46, in which (i,j) is the pixel at the ith row and jth column in the image and/or on the back LCD panel 46. Similarly, I_{i,j} may represent the pixel value at (i,j) in the incoming original image (e.g., as illustrated process step and image 138). The term dr may represent the dynamic range, and may be computed, for example, by dividing the maximal and minimal luminance of the back LCD panel 46. Thus, in certain embodiments, the complete term

$$max ( \frac{1}{dr} , {I}_{i , j} )$$

may represent a lower constraint of the objective function (e.g., equation (1)). Similarly, the complete term min (dr×I_{i,j},1) may represent an upper constraint of the objective function (e.g., equation (1)). Specifically, as the objective function (e.g., equation (1)) measures the smoothness and/or blurring of the image of the back LCD panel 46, the lower constraint

$$max ( \frac{1}{dr} , {I}_{i , j} )$$

and the upper constraint min (dr×I_{i,j},1) may be used to restrict or limit the solution search of the objective function to only solutions within the bounds of the lower constraint

$$max ( \frac{1}{dr} , {I}_{i , j} )$$

and the upper constraint min (dr×I_{i,j},1).

For example, assuming the back LCD panel 46 includes a dynamic range of approximately 1000:1 (e.g., dr=1000) and that I_{i,j} is between approximately 0 and 1, the term (dr×I_{i,j},1) may be always less than 1 except for very dark pixels. Therefore, the upper constraint min (dr×I_{i,j},1) may be provided to avoid over-exposing dark pixels on the back LCD panel 46. Similarly, because I_{i,j} may be greater than

$$\frac{1}{dr}$$

for most pixels, the lower constraint may be provided to retain most of the dynamic range of the original image and to avoid under-exposing brighter pixels, which may cause over-compensation (e.g., clipping artifacts) on the front LCD panel 48.

In certain embodiments, referring again to FIG. 9, it may be useful to begin with the upper constraint min (dr×I_{i,j},1) when blurring the image of the back LCD panel 46 as illustrated, for example, by process step and image 140. Specifically, the upper constraint min (dr×I_{i,j},1) may be used as a starting point of the objective function (e.g., equation (1)) during the search for the “best” possible solution of the objective function (e.g., equation (1)). In this way, blurring of the image of the back LCD panel 46 may be achieved to prevent parallax, while concurrently preventing bright pixels from being excessively dimmed, which would otherwise later appear as clipping artifacts in the image of the front LCD panel 48.

Referring again to FIG. 9, the process 136 (e.g., image splitting algorithm(s) 134) may continue with the GPUs 130 downsampling and normalizing (process step and image 146) the split image provided to the back LCD panel 46. More specifically, in certain embodiments, the GPUs 130 may interpolate (e.g., downsample) the split image provided to the back LCD panel 46 to reduce noise and to lower computational cost during the blurring. Specifically, the GPUs 130 may downsample the split image provided to the back LCD panel 46 by, for example, reducing a number of bits required for acceptable display of the split image of the back LCD panel 46. In one embodiment, as will be further appreciated, the split image provided to the back LCD panel 46 may be downsampled a second time when the physical resolution of the back LCD panel 46 is lower than the physical resolution of front LCD panel 48.

The process 136 (e.g., image splitting algorithm(s) 134) may continue with the GPUs 130 applying a guided filter to, and normalizing (process step and image 148) the split image provided to the back LCD panel 46. In certain embodiments, the guided filter may include any software filter, hardware filter, or a filter including a combination of software and hardware that may serve as an image edge-preserving smoothing operator that filters the split image provided to the back LCD panel 46 based on, for example, the geometrical distance between the pixels (e.g., pixels 102) of the back LCD panel 46 and the intensity difference between the pixels (e.g., pixels 102) of the back LCD panel 46.

Indeed, by applying a guided filter on the downsampled split image of the back LCD panel 46, and, by extension, considering the intensity or brightness difference between neighboring pixels (e.g., pixels 102), the uniformity of the image of the back LCD panel 46 may be improved. Furthermore, the guided filter may allow the image to be smoothed while concurrently preserving the edges (e.g., edges of the entire image as well as edges of the individual elements within the image) in the image. In other embodiments, a Gaussian filter, bi-lateral, or similar filter may be used. The split image of the back LCD panel 46 may be then normalized to retrieve the dynamic range of the incoming image (e.g., original image) because the blurring may excessively dim bright pixels. These techniques may reduce and/or prevent possible occurrences of halos (e.g., image artifacts appearing near the edges of an image and/or near the edges of elements within the image) or other undesirable image artifacts from becoming apparent when the image is viewed from the front LCD panel 48.

The process 136 (e.g., image splitting algorithm(s) 134) may then continue with the GPUs 130 upsampling (process step and image 150) the split image provided to the back LCD panel 46. For example, the GPUs 130 may be upsampled (e.g., increasing the number of pixel points of the image) to recover the resolution of the incoming image (e.g., original image). As further depicted by FIG. 9, the process 136 (e.g., image splitting algorithm(s) 134) may then continue with the GPUs 130 downsampling (process step and image 152) the previously downsampled, filtered and normalized, and upsampled split image of the back LCD panel 46 when the physical resolution of the back LCD panel 46 is lower than the physical resolution of front LCD panel 48. For example, in one embodiment, the back LCD panel 46 may include a pixel resolution of approximately 1 k to 2 k (e.g., from approximately 1024×768 to approximately 2048×1080), and the front LCD panel 48 may include a pixel resolution of approximately 2 k to 4 k (e.g., from approximately 2048×1080 to approximately 3840×2160 or 4096×2160) or higher. Furthermore, in some embodiments, the luminance of the dual-layer display 18 may be increased by providing a monochromatic back LCD panel 46 that includes a higher aperture ratio and lower resolution as compared to the front LCD panel 48. This may improve the overall light efficiency of the dual-layer display 18.

The process 136 (e.g., image splitting algorithm(s) 134) may then conclude with the GPUs 130 combining (process step and image 154) the previously downsampled, filtered and normalized, and upsampled split image (e.g., as illustrated by process step and image 152) provided to the back LCD panel 46 and the split original image (e.g., as illustrated by process step and image 142) to be displayed on the front LCD panel 48. Thus, the image (e.g., as illustrated by process step and image 154) displayed on the front LCD panel 48 of the dual-layer display 18 may include a high contrast ratio, high dynamic range (HDR), and high bit depth while avoiding certain possible image artifacts (e.g., parallax, halos, clipping artifacts, and so forth).

Simulation examples of images including, for example, image artifacts (e.g., parallax artifacts, halos, clipping artifacts, and so forth) as compared to similar images generated on the dual-layer display 18 using the presently disclosed reduced hardware and image-splitting techniques were generated. For example, an image generated without using the presently disclosed techniques included parallax artifacts, in which elements of the image may appeared as an overlapping double image as may be especially observed near text or the edges of one or more elements of the image. In contrast, an image generated on the dual-layer display 18 according to the presently disclosed techniques reduced and eliminated parallax in the image.

In a similar example, simulation examples of a luminance map of an image on a single panel LCD display as compared to a dual-layer display implementing the presently disclosed reduced hardware and image-splitting techniques were generated. In the present example, luminance was computed at each pixel by weighing the red, green, and blue channels (e.g., 0.2:0.7:0.1), and then normalizing the image between approximately 0 and 1. The images were generated according to log₁₀(Y). For example, an image produced by a single panel display having a contrast ratio of approximately 1000:1. However, because of light leakage that is experienced by single panel displays, the dynamic range of illustrated in the image is approximately [0,−3] (e.g., maximum value of 0 and minimum value of log₁₀(0.001)).

On the other hand, a similar image generated on a dual-layer (e.g., dual-cell) display 18 and according to the reduced hardware and image-splitting techniques of the present embodiments was generated. Specifically, in the dual layer image, the dynamic range is increased to approximately [0, −6] (e.g., maximum value of 0 and minimum value of log₁₀(0.000001)). In one instance, it was observed that while the luminance of bright areas in the single layer image was generally commensurate with the luminance of the bright areas in the dual-layer image, the dark areas in the dual-layer image appeared considerably darker as compared to the single layer image because the contrast ratio had been increased. Thus, as previously discussed, the present techniques may provide high contrast and high dynamic range (HDR) images while compensating for certain image artifacts (e.g., parallax, halos, clipping artifacts, and so forth) that may otherwise become apparent in the images. These techniques may be particularly useful for viewing conditions where ambient light may not be dominant, such as, for example, in televisions or computers in indoor environments.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

What is claimed is:

1. A system, comprising:
an enclosure, comprising:
a first display panel;
a second display panel, wherein the second display panel is coupled to the first display panel; and
one or more processors communicatively coupled to the first display panel and the second display panel, and configured to:
generate a first image;
generate a second image to be displayed on the first display panel based at least in part on the first image;
interpolate the second image, wherein interpolating the second image comprises adjusting the second image according to a generated objective function bounded by a first constraint;
filter the second image; and
generate a third image to be displayed on the second display panel based at least in part on the first image and the interpolated and filtered second image, wherein the third image is generated to reduce or substantially prevent an occurrence of image artifacts on the second display panel.

2. The system of claim 1, wherein the first display panel comprises a first plurality of pixels configured to display grayscale images.

3. The system of claim 1, wherein the second display panel comprises a second plurality of pixels configured to display color images.

4. The system of claim 1, wherein the one or more processors are configured to adjust the second image according to the generated objective function by starting with an upper constraint as the first constraint.

5. The system of claim 1, wherein the one or more processors are configured to adjust the second image according to the generated objective function bounded by the first constraint and a second constraint, and wherein the first constraint comprises an upper constraint of the objective function and the second constraint comprises a lower constraint of the objective function.

6. The system of claim 1, wherein the one or more processors are configured to filter the second image by applying a guided filter to smooth and increase uniformity of the second image.

7. The system of claim 1, wherein the third image comprises a contrast ratio approximately equal to a product of a contrast ratio of the first display panel and a contrast ratio of the second display panel.

8. The system of claim 1, wherein the image artifacts comprise a parallax image artifact, a halo image artifact, a clipping image artifact, or any combination thereof.

9. A method of manufacturing a dual-cell electronic display, comprising:
providing a first display panel and a second display panel in a substantially stacked configuration, wherein the stack of the first display panel and the second display panel comprises:
a light source layer configured to provide a source of light to the first display panel;
a first polarizing layer of the first display panel disposed above the light source layer and configured to polarize the source of the light;
a first transistor layer of the first display panel disposed above the first polarizing layer;
a first liquid crystal layer of the first display panel disposed above the first transistor layer, wherein the first liquid crystal layer is electrically coupled to the first transistor layer and configured to modulate the polarized source of light at a first instance;
a second transistor layer of the second display panel disposed above the first liquid crystal layer;
a second liquid crystal layer of the second display panel disposed above the second transistor layer, wherein the second liquid crystal layer is electrically coupled to the first transistor layer and configured to modulate the polarized source of light at a second instance; and
a second polarizing layer of the second display panel disposed above the second liquid crystal layer.

10. The method of claim 9, wherein providing the first display panel and the second display panel comprises stacking the second display panel substantially atop the first display panel.

11. The method of claim 10, comprising electrically coupling the first display panel to the second display panel, and wherein the second display panel is configured to display one or images to be viewed by a user of the dual-cell electronic display.

12. The method of claim 9, wherein the stack of the first display panel and the second display panel does not include a diffuser layer or an air gap layer.

13. The method of claim 9, wherein the first display panel does not include a top polarizing layer, and wherein the second display panel does not include a bottom polarizing layer.

14. The method of claim 9, comprising including a color filter between the second polarizing layer and the second liquid crystal layer of the second display panel and excluding a color filter from the first display panel.

15. A method for displaying an image on a dual-layer electronic display, comprising:
receiving an incoming image via the dual-layer electronic display;
splitting the incoming image into a first image to be displayed on a back display panel of the dual-layer electronic display and a second image to be displayed on a front display panel of the dual-layer electronic display;
blurring the first image according to a generated objective function based at least in part on an upper constraint of the objective function;
applying a filter to the first image to smooth and increase a uniformity of the first image; and
generating a third image to be displayed on the front display panel based at least in part on the first image and the second image, wherein the third image is generated to reduce or substantially eliminate an occurrence of a parallax artifact or a halo artifact on the front display panel.

16. The method of claim 15, wherein blurring the first image according to the generated objective function comprises searching for a solution of the objective function by starting with the upper constraint.

17. The method of claim 15, wherein applying the filter to the second image comprises applying a guided filter to smooth the second image and to retain apparent edges of the incoming image within the first image.

18. The method of claim 15, comprising downsampling and normalizing the first image prior to applying the filter to the first image.

19. The method of claim 15, wherein generating the third image comprises combining the first image and the second image to be displayed on the front display panel.

20. The method of claim 15, wherein generating the third image comprises generating a high dynamic range (HDR) and higher contrast ratio image as compared to the incoming image or the first image.

21. An electronic device, comprising:
a first liquid crystal display (LCD) panel including a first plurality of pixels;
a second LCD panel including a second plurality of pixels, wherein the second LCD panel is electrically coupled to the first LCD panel; and
a graphics processing unit (GPU) configured to provide image data to the first plurality of pixels and the second plurality of pixels and to execute one or more image-splitting processes comprising:
splitting an original image into a grayscale image to be displayed on the first LCD panel and a color image to be displayed on the second LCD panel;
blurring the grayscale image according to one or more objective functions, wherein a solution search of the one or more objective functions is initialized based on an upper bound constraint of the objective function;
downsampling and normalizing the grayscale image to reduce a noise parameter of the grayscale image;
applying a guided filter on the grayscale image to uniformize the grayscale image; and
combining the grayscale image and the color image to produce a viewable image to be displayed on the second LCD panel, wherein the viewable image is produced to reduce or substantially prevent an occurrence of image artifacts on the second LCD panel.

22. The electronic device of claim 21, wherein the first LCD panel comprises a lower pixel resolution than the second LCD panel.

23. The electronic device of claim 22, wherein the first LCD panel comprises a pixel resolution of approximately 1 k to 2 k, and wherein the second LCD panel comprises a pixel resolution of approximately 2 k to 4 k.

24. A non-transitory computer-readable medium having computer executable code stored thereon, the code comprising instructions to:
generate a first image to be displayed on a back panel or a front panel of a dual layer high dynamic range (HDR) electronic display;
generate a second image to be displayed on the back panel based on the first image;
interpolate the second image, wherein interpolating the second image comprises adjusting the second image according to a generated objective function bounded by a first constraint;
apply a filter to the second image; and
generate a third image to be displayed on the front panel based on the first image and the interpolated and filtered second image, wherein the third image is generated to reduce or substantially eliminate an occurrence of a parallax artifact or a halo artifact on the front panel.
